(19) United States
(12) Patent Application Publication
(10) Pub. No.: US 2012/0074563 A1
(43) Pub. Date: Mar. 29, 2012

(54) Semiconductor apparatus and the method of manufacturing the same

(75) Inventor: Yuji Iizuka, Matsumoto-shi (JP)

(73) Assignee: Fuji Electric Co., Ltd., Kawasaki-shi (JP)

(21) Appl. No.: 13/200,377

(22) Filed: Sep. 23, 2011

(30) Foreign Application Priority Data
Sep. 28, 2010 (JP) 2010-216494

(51) Int. Cl. H01L 23/488; B23K 31/02; B23K 1/20

(52) U.S. Cl. 257/737; 228/248.1; 257/E23.023

(57) ABSTRACT

A semiconductor apparatus includes a semiconductor chip, a post electrode positioned on the front surface electrode, and a metal particle layer having metal particles bonded actively to each other. The front surface electrode and the post electrode are bonded with each other through the metal particle layer. A method of manufacturing a semiconductor apparatus includes the steps of coating metal particles protected with organic coating films to at least one of the front surface electrode of a semiconductor chip or the post electrode; pressing and heating the metal particles between the front surface electrode of the semiconductor chip and post electrode for breaking the organic coating films and for exposing the metal particles; and actively bonding the exposed metal particles to each other for bonding the front surface electrode and post electrode.

### FIELD OF THE INVENTION

The present invention relates to semiconductor apparatuses using power semiconductor devices and the method of manufacturing the semiconductor apparatuses.

### BACKGROUND

Power semiconductor devices are incorporated into a semiconductor module to constitute a semiconductor apparatus and used as switching devices in an electric power converter.

FIG. 5 shows the structure of a semiconductor module as a semiconductor apparatus.

In FIG. 5, insulator baseboard 2 is bonded onto heat sink (radiator base) 3 made of a very high thermally conductive material. Insulator baseboard 2 includes ceramic substrate 2b. On one surface (back surface) of ceramic substrate 2b, back surface pattern 2a is formed. On the other surface (front surface) of ceramic substrate 2b, electrical-conductor pattern 2c is formed. Back surface pattern 2a is bonded to heat sink 3.

Semiconductor chip 1, which is a power semiconductor device, includes a back surface electrode bonded to electrical-conductor pattern 2c of insulator baseboard 2. Semiconductor chip 1 includes also a front surface electrode connected via aluminum wires 5 to electrical-conductor pattern 2c of insulator baseboard 2 and to a not-shown lead-through terminal for an external connection.

The bonded unit including semiconductor chip 1, insulator baseboard 2, and heat sink 3 is housed in resin case 6 and fixed to radiator fins 4.

Recently, renewable power plant intended for saving power is used more widely and the needs for the power converters applicable to the power plant are increasing. It is required for the semiconductor modules used in the power converters to exhibit a large capacity.

Aluminum wires 5 are used in the semiconductor module shown in FIG. 5 for connecting the front surface electrode of semiconductor chip 1 to the electrical-conductor pattern or to the lead-through terminal. When the semiconductor module shown in FIG. 5 is applied to the power converters described above, the reliability of the semiconductor module in making a high current flow is determined by the bonding strength between a wiring stuff such as aluminum wire 5 and semiconductor chip 1.

Especially for applying compound semiconductors employed more often in these days and operable at a high temperature, it is required to provide semiconductor chip 1 with a bonding structure that endures high temperature operations.

To meet the requirements described above, the following Patent Documents 1 and 2 propose the use of a connecting part obtained by forming a post-shaped electrode on an insulator part instead of the aluminum wire for connecting the front surface electrode of the semiconductor chip and the lead-through terminal to each other.

### DOCUMENTS DESCRIBING THE PRIOR ARTS

### Patent Documents

[Patent Document 1] Japanese Unexamined Patent Application Publication No. 2006-237429 (FIG. 1 etc.)

[Patent Document 2] Japanese Unexamined Patent Application Publication No. 2009-64852 (FIG. 1 etc.)

The aluminum wires employed in the semiconductor module shown in FIG. 5 generate heat when a high current is made to flow through the aluminum wires. Due to the heat generation, a stress caused by the thermal coefficient difference between the aluminum wire and the front surface electrode of semiconductor chip 1 is exerted to the junction portion of the aluminum wire and the front surface electrode of semiconductor chip 1.

In the structures described in the Patent Documents 1 and 2, it is difficult to bond the post-shaped electrode to the front surface electrode of the semiconductor chip securely.

In view of the foregoing, it would be desirable to obviate the problems described above. It would be also desirable to provide a semiconductor apparatus that facilitates relaxing the thermal stress caused by making a high current flow using a post-shaped electrode and bonding the post-shaped electrode to the electrode on the semiconductor chip securely. It would be further desirable to provide a method of manufacturing the semiconductor apparatus as described above.

### SUMMARY OF THE INVENTION

According to an aspect of the invention, there is provided a method of manufacturing a semiconductor apparatus that includes a semiconductor chip including a front surface electrode, and a post electrode bonded to the front surface electrode, the method including the steps of:

coating metal particles, each protected with an organic coating film, to any or both of the front surface electrode and the bonding plane of the post electrode; and

pressing and heating the metal particles between the front surface electrode and the bonding plane of the post electrode for breaking the organic coating films to expose the metal particles, and bonding the exposed metal particles actively with each other to form a first bonding layer, through which the front surface electrode and the post electrode are bonded to each other.

Also, the method further includes the step of liquefying a bonding agent, which liquefies by re-heating at a temperature higher than the temperature of the heating, around the first bonding layer for forming a second bonding layer bonded to the front surface electrode, the post electrode, and the first bonding layer.

Also, the bonding agent is a solder that does not contain lead, and the solder is liquefied at the temperature of the re-heating higher than the solid-phase-curve temperature of the solder.

According to the invention, the productivity of the semiconductor apparatuses is not impaired and the capacities of the power converters are increased efficiently.

### BRIEF DESCRIPTIONS OF THE DRAWINGS

FIG. 1(a) shows the entire structure of a semiconductor apparatus according to a first embodiment of the invention.

FIG. 1(b) is a sectional view of the region A surrounded by the broken lines in FIG. 1(a).

FIG. 2(a) shows the entire structure of a semiconductor apparatus according to a second embodiment of the invention.

FIG. 2(b) is the sectional view of the region B surrounded by the broken lines in FIG. 2(a).

FIG. 3(a) shows the entire structure of a semiconductor apparatus according to a third embodiment of the invention.

FIG. 3(b) is the sectional view of the region C surrounded by the broken lines in FIG. 3(a).

FIG. 4(a) shows the entire structure of a semiconductor apparatus in the state thereof after the bonding according to the second and third embodiments.

FIG. 4(b) is the sectional view of the region D surrounded by the broken lines in FIG. 4(a).

FIG. 5 shows the entire structure of a conventional semiconductor apparatus.

### MODES FOR CARRYING OUT THE INVENTION

Now the invention will be described in detail hereinafter with reference to the accompanied drawings which illustrate the preferred embodiments of the invention.

### First Embodiment

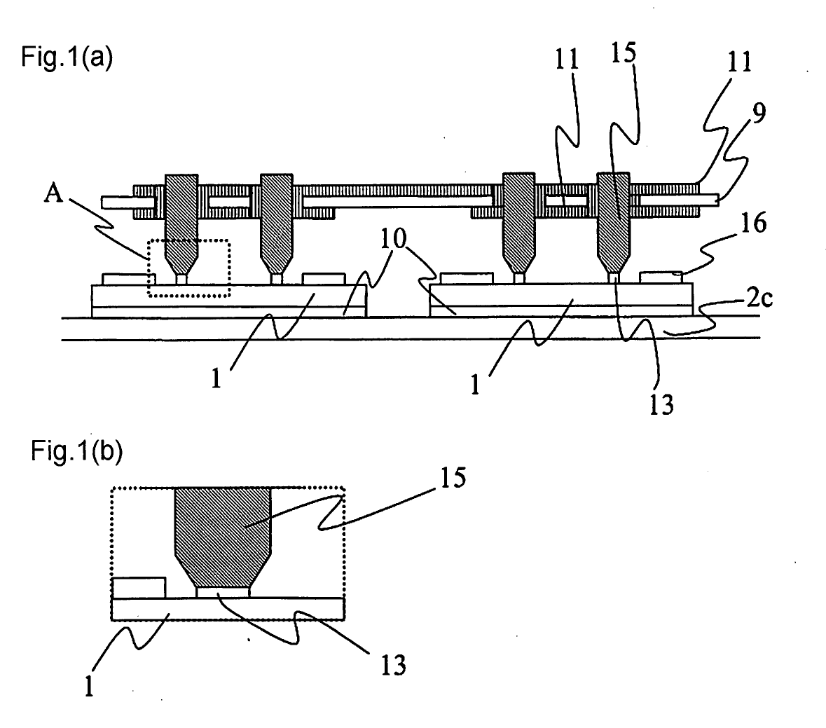

FIG. 1(a) shows the entire structure of a semiconductor apparatus according to a first embodiment of the invention. FIG. 1(b) is the sectional view of the region A surrounded by the broken lines in FIG. 1(a).

In FIG. 1(a), semiconductor chip 1 is bonded to electrical-conductor pattern 2c of an insulator baseboard via bonding agent 10. The insulator layer of the insulator baseboard is not shown in FIGS. 1(a) and 1(b).

The semiconductor chip is a chip of a switching device such as an IGBT and a MOSFET or a chip of a free-wheeling diode (FWD). The semiconductor chip is formed on a silicon substrate, or on a compound semiconductor substrate such as a silicon carbide (SiC) substrate and a gallium nitride (GaN) substrate.

Electrical-conductor pattern 11 is formed at least on one surface of insulator layer 9 of a wiring baseboard. Through-holes are bored through the wiring baseboard. Post electrode 15, which is an electrical conductor, is inserted into the through-hole. Post electrode 15 is connected to electrical-conductor pattern 11. Post electrodes 15 shown in FIG. 1(a) are connected to common electrical-conductor pattern 11. Alternatively, post electrodes 15 may be connected to different electrical-conductor patterns 11 depending on the circuit configurations.

In the structure shown in FIG. 1(a), electrical-conductor pattern 11 is formed also on the side wall of the through-hole to secure the connection between electrical-conductor pattern 11 and post electrode 15.

Bonding layer 13 bonds post electrode 15 and the front surface electrode (not-shown) of semiconductor chip 1 with each other. Bonding layer 13 is a layer of very fine metal particles of several nm to several hundreds nm in diameter actively bonded between the solid phases.

Now the method of manufacturing the semiconductor apparatus shown in FIGS. 1(a) and 1(b) will be described below.

First, semiconductor chip 1 is fixed to electrical-conductor pattern 2c of an insulator baseboard via bonding agent 10.

Then, a first bonding agent, which hardens to form bonding layer 13, is coated to a predetermined portion on the front surface electrode of semiconductor chip 1 and/or to the bonding portion of post electrode 15, inserted through the wiring baseboard. In the bonding portion, the post electrode 15 is bonded to semiconductor chip 1. (The state of the first bonding agent not hardened yet is not illustrated.)

The first bonding agent includes very fine metal particles of several nm to several hundreds nm in diameter, an organic coating film (surface protection film) that protects each metal particle surface, and a volatile binder that makes the treatment of the first bonding agent easy. Since the first bonding agent is creamy before the state of bonding (before the heated state), the desired amount of the bonding agent is dropped (or painted) on the desired position in the bonding portion using a dispenser, for example.

According to the first embodiment, the first bonding agent is coated on the front surface electrode of semiconductor chip 1 and/or to the bonding portion of post electrode 15 between post electrode 15 and semiconductor chip 1.

Then, the wiring baseboard is mounted on semiconductor chip 1 such that post electrode 15 is positioned on the front surface electrode of semiconductor chip 1.

Subsequently, the wiring baseboard or post electrode 15 is weighed to press the first bonding agent between post electrode 15 and the front surface electrode of semiconductor chip 1. The first bonding agent, pressed between post electrode 15 and the front surface electrode on semiconductor chip 1, is placed in a furnace or heated locally such that the bonding portion is heated at a temperature between 200° C. and 250° C.

The binder component in the first bonding agent is vaporized by heating. Further, the surface protection film on the metal particle is decomposed thermally and the metal particle surface is exposed. As the surface protection films are decomposed, the metal particle surfaces are exposed and the bonding activities of the metal particle surfaces are improved. As a result, welding and sintering proceed between the activated metal particles, between the activated metal particles and post electrode 15, and between the activated metal particles and the front surface electrode of semiconductor chip 1. In other words, dense bonding layer 13 is formed utilizing the active bonding between dense solid phases.

The metal particle is the particle of a pure material classified into the precious metal such as Au, Ag, Cu, Pd, and Pt, or the particle of an alloy such as Ag—Pd, Au—Si, Au—Ge, and Ag—Cu.

When the metal particle contains a precious metal only, a strong bonding layer (sintered layer) is obtained by the heating at a temperature between 200° C. and 250° C. Once bonded, the bonding layer exhibits the resistance against the melting point of the original metal (roughly from 800° C. to 1100° C.). When an alloy composition is employed, the bonding layer exhibits the resistance against a temperature roughly between 280° C. and 700° C.

In the step of bonding the front surface electrode of semiconductor chip 1 and a post electrode with each other, the bonding portion is heated at a temperature between 200° C. and 250° C. Therefore, a material, resistive against the heating at the temperature between 200° C. and 250° C., is employed for bonding agent 10 for bonding semiconductor chip 1 and the electrical-conductor pattern of the insulator baseboard with each other.

As described above, semiconductor chip 1 and post electrode 15 is bonded with each other strongly.

### Modified Example 1

According to the first embodiment, the front surface electrode of semiconductor chip 1 and post electrode 15 are bonded with each other with metal particles after semiconductor chip 1 is bonded to the electrical-conductor pattern of the insulator baseboard. The bonding employing metal particles may be applied also to the bonding of the back surface electrode (not shown) of semiconductor chip 1 and electrical-conductor pattern 2c of the insulator baseboard.

In other words, it is possible to employ the first bonding agent for bonding agent 10 shown in FIG. 1(a). First, the first bonding agent is coated on a desired position on electrical-conductor pattern 2c of the insulator baseboard and semiconductor chip 1 is mounted on electrical-conductor pattern 2c. Then, the first bonding agent is coated also on the front surface electrode of semiconductor chip 1 and a wiring baseboard is mounted on semiconductor chip 1 such that post electrode 15 is positioned on the first bonding agent coated. Then, the wiring baseboard (or post electrode 15) is weighed, and the first bonding agent between electrical-conductor pattern 2c of the insulator baseboard and the back surface electrode of semiconductor chip 1 and the first bonding agent between the front surface electrode of semiconductor chip 1 and post electrode 15 are sintered simultaneously to form bonding layers therebetween.

### Second Embodiment

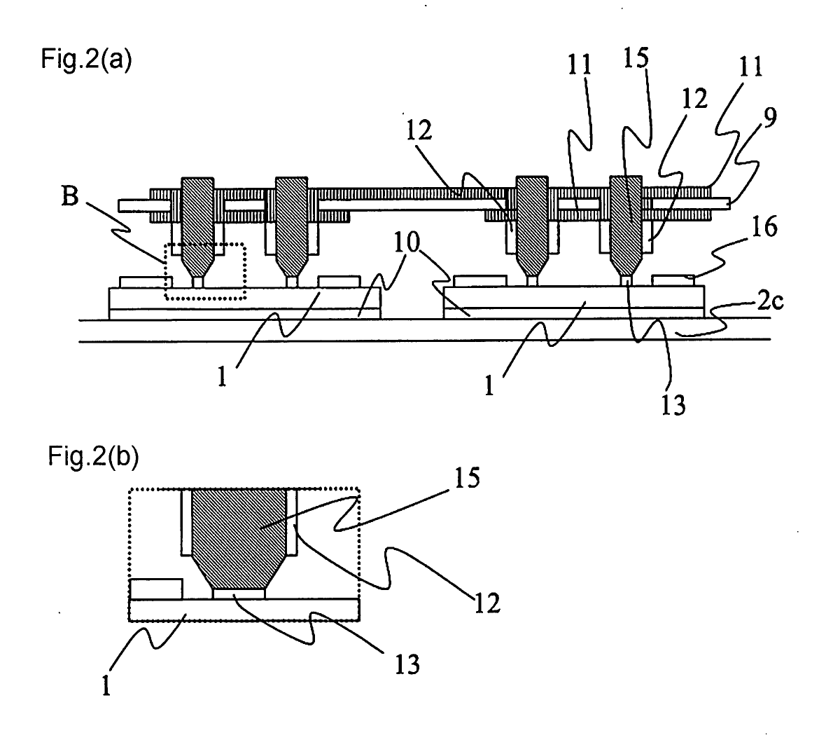

FIG. 2(a) shows the entire structure of a semiconductor apparatus according to a second embodiment of the invention. FIG. 2(b) is the expanded view of the region B surrounded by the broken lines in FIG. 2(a).

In FIGS. 2(a) and 2(b), the same reference numerals as used in FIGS. 1(a) and 1(b) are used to designate the same constituent elements and their duplicated descriptions are omitted for the sake of simplicity.

The semiconductor apparatus shown in FIGS. 2(a) and 2(b) is different from the semiconductor apparatus shown in FIGS. 1(a) and 1(b) in that second bonding agent 12 is disposed on the exposed side wall of a post electrode in advance.

Semiconductor chip 1 is fixed to electrical-conductor pattern 2c of insulator baseboard 2. The first bonding agent is coated on the front surface electrode of semiconductor chip 1 and bonding layer 13 is formed between the front surface electrode of semiconductor chip 1 and a post electrode in the same manner as according to the first embodiment to bond the front surface electrode of semiconductor chip 1 and the post electrode to each other.

For second bonding agent 12, the general paste of a non-lead type solder such as a Sn—Ag solder, a Sn—Ag—Cu solder, a Sn—Sb solder, a Bi solder, a Bi—Ag solder, and a Bi—Cu solder is employed.

Second bonding agent 12 as described above is coated on the exposed side wall of a post electrode in advance. After the bonding that employs the first bonding agent is completed, the assembled structure shown in FIG. 2(a) is made to pass through a reflow furnace to heat second bonding agent 12 at a temperature between 260° C. and 330° C. under no pressure.

Second bonding agent 12 is liquefied by the reflow heating. Liquefied second bonding agent 12 flows down the post electrode side wall and spreads to wet the side wall of bonding layer 13 made of a first bonding agent.

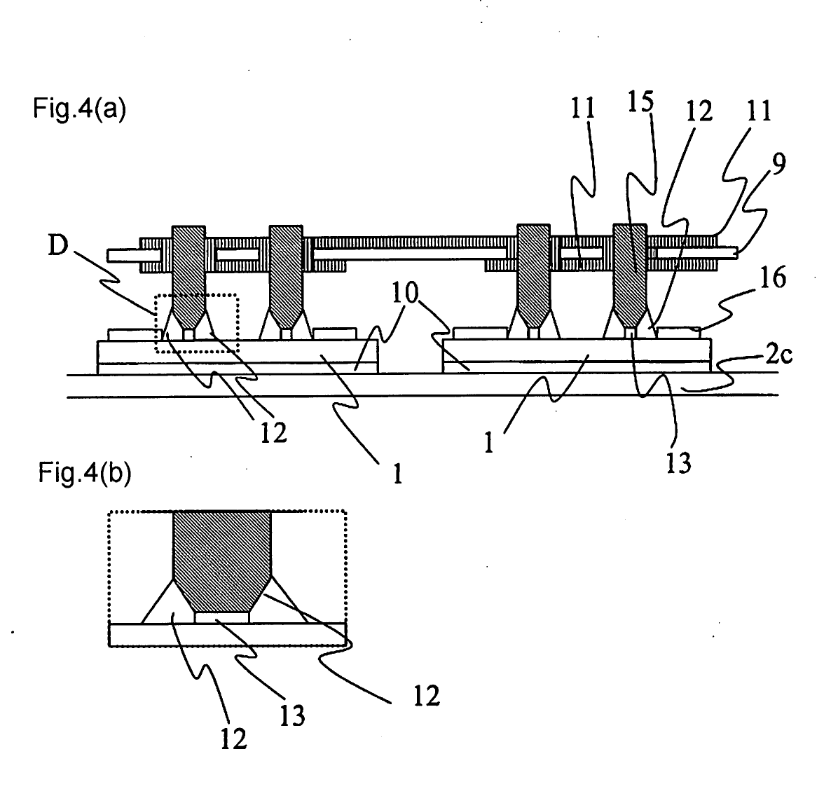

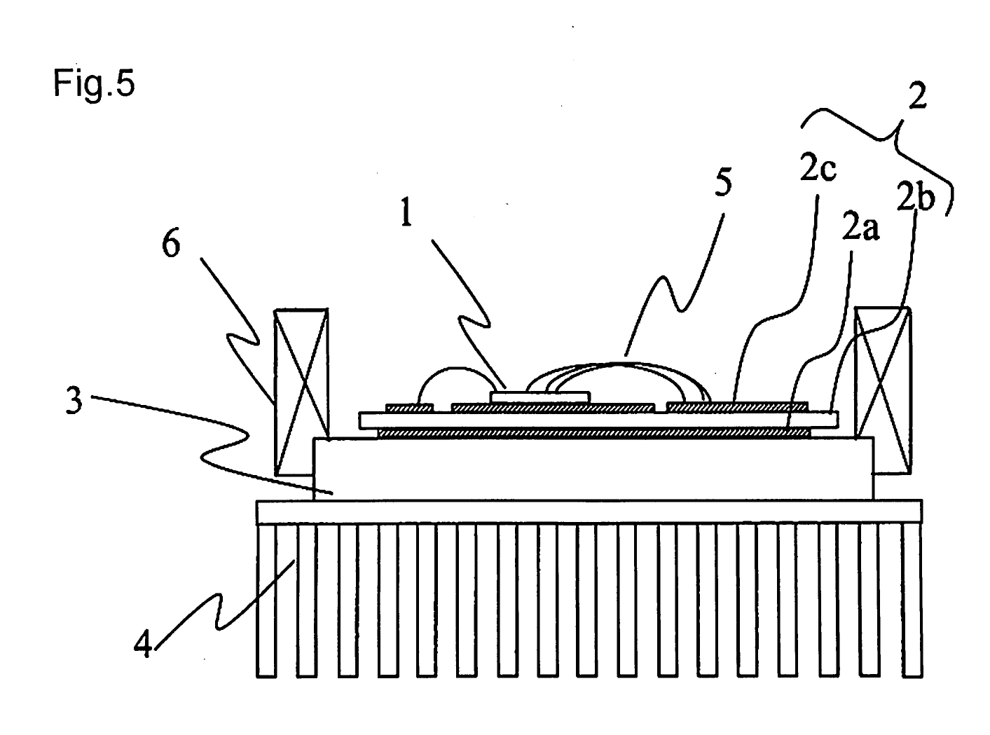

FIG. 4(a) shows the entire structure of a semiconductor apparatus in the state thereof after the bonding according to the second embodiment and according to a third embodiment of the invention. FIG. 4(b) is the expanded view of the region D surrounded by the broken lines in FIG. 4(a).

As shown in FIGS. 4(a) and 4(b), second bonding agent 12 is liquefied by the reflow heating, flows down the side wall of bonding layer 13, and forms a fillet-shaped end-portion-supporting structure. Second bonding agent 12 penetrates the porous portion of bonding layer 13. Since bonding layer 13, post electrode 15, and semiconductor chip 1 are bonded into a unit by second bonding agent 12, a structure, in which the bondings are strengthened, is obtained.

Any of the non-lead type solders described above may be used for second bonding agent 12 and the paste of the non-lead type solder selected may be coated without a problem. Alternatively, any of the non-lead type solders described above may be sputtered or plated to form a surface film on electrical-conductor pattern 11 in advance.

### Third Embodiment

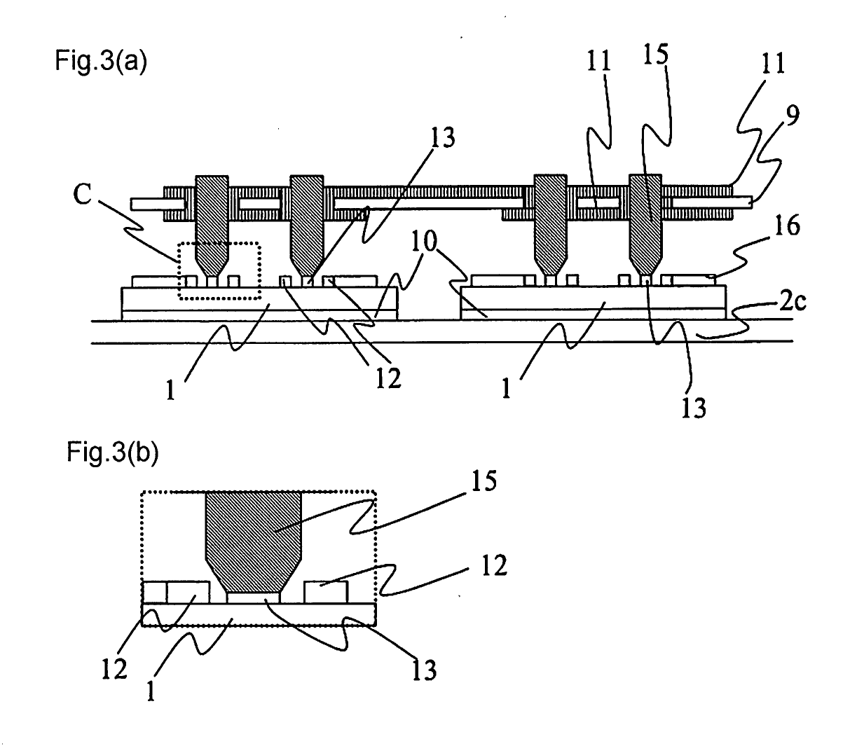

FIG. 3(a) shows the entire structure of a semiconductor apparatus according to a third embodiment of the invention. FIG. 3(b) is the expanded view of the region C surrounded by the broken lines in FIG. 3(a).

In FIGS. 3(a) and 3(b), the same reference numerals as used in FIGS. 2(a) and 2(b) are used to designate the same constituent elements and their duplicated descriptions are omitted for the sake of simplicity.

The semiconductor apparatus according to the third embodiment is different from the semiconductor apparatus shown in FIG. 2(a) in that a second bonding agent is coated on the front surface electrode of a semiconductor chip. The second bonding agent is a non-lead type solder in the same manner as according to the second embodiment.

In the same manner as according to the second embodiment, the first bonding agent is coated on the front surface electrode of semiconductor chip 1 and bonding layer 13 is formed between the front surface electrode of semiconductor chip 1 and a post electrode to bond the front surface electrode of semiconductor chip 1 and the post electrode with each other with bonding layer 13 in the same manner as according to the first embodiment.

After the bonding with the first bonding agent is completed, the assembled structure shown in FIG. 3(a) is made to pass through a reflow furnace to heat the second bonding agent at a temperature between 260° C. and 330° C. under no pressure.

Second bonding agent 12 is liquefied by the reflow heating. Liquefied second bonding agent 12 spreads to wet the front surface electrode of semiconductor chip 1, spreads further to wet the side wall of bonding layer 13 made of the first bonding agent, and forms a fillet-shaped end-portion-supporting structure as shown in FIGS. 4(a) and 4(b). Second bonding agent 12 penetrates the porous portion of bonding layer 13. Since bonding layer 13, post electrode 15, and semiconductor chip 1 are bonded into a unit by second bonding agent 12, a structure in which the bondings are strengthened is obtained.

Any of the non-lead type solders described above may be used for second bonding agent 12 and the paste of the non-lead type solder selected may be coated without a problem. Alternatively, any of the non-lead type solders described above may be sputtered or plated to form a surface film on electrical-conductor pattern 11 in advance.

Now the semiconductor apparatuses according to the second and third embodiments will be described in connection with the use of pure silver (Ag) particles for the first bonding agent.

Bonding agents which employ pure silver (Ag) particles have been used widely. The pure silver particles (nano-particles) from several nm to several hundreds nm in diameter are used.

When the bonding agent that employs pure silver particles is used, the bonding portion between the front surface electrode of the semiconductor chip and the post electrode is heated up to around 250° C. By the heating, a sintered compact of pure silver particles (nano-particles) is formed.

Even by the bonding only with pure silver particles according to the first embodiment, the front surface electrode of the semiconductor chip and the post electrode are bonded to each other strongly.

However, porous defects are caused in the edge area of bonding layer 13 sometimes.

To obviate the problem described above, a non-lead type solder such as a solder of Bi-2.5Ag, the melting point of which is 271° C., is used as a second bonding agent in the same manner as according to the second and third embodiments. If the non-lead type solder is coated on the side wall of a post electrode or on the front surface electrode of a semiconductor chip in advance and the solder is melted, after the bonding with bonding layer 13, to perform liquid-phase bonding, the solder will spread to wet the side wall of the post electrode or the front surface electrode of the semiconductor chip. And, the molten solder will penetrate and diffuse into the porous detects caused in bonding layer 13. Moreover, since inter-metal bondings are formed on the boundary between the Ag particles and the solder, the united structure bonded by bonding layers 13 is further strengthened.

In FIGS. 1(a), 2(a), 3(a), and 4(a), a passivation layer or a resist layer designated by the reference numeral 16 is formed on the semiconductor chip surface. Especially in the structures shown in FIGS. 2(a), 3(a), and 4(a), passivation layer 16 or resist layer 16 functions as a solder dam that prevents the solder as a molten second bonding agent from sticking to an unintended location.

As shown in FIGS. 1(a) through 4(b), the edge portion of the post electrode 15 surface on the side of the front surface electrode of the semiconductor chip is chamfered. The chamfering facilitates focusing the pressure applied to the first bonding agent between post electrode 15 and the front surface electrode of the semiconductor chip to the bonding plane. By focusing the applied pressure, the bonding between post electrode 15 and the front surface electrode of the semiconductor chip is strengthened.

Especially in the structures shown in FIGS. 2(a) through 4(b), the chamfered edge portion of the post electrode 15 surface facilitates making the molten second bonding agent creep up post electrode 15 and form a solder fillet, which strengthens the bonding between post electrode 15 and the front surface electrode of the semiconductor chip.

The disclosure of Japanese Patent Application No. 2010-216494 filed on Sep. 29, 2010 is incorporated herein as a reference.

While the invention has been explained with reference to the specific embodiments of the invention, the explanation is illustrative and the invention is limited only by the appended claims.

What is claimed is:

1. A semiconductor apparatus comprising:
a semiconductor chip having a front surface electrode;
a post electrode positioned on the front surface electrode; and
an actively bonded metal particle layer bonding the front surface electrode and the post electrode.

2. A semiconductor apparatus according to claim 1, wherein the actively bonded metal particle layer comprises a plurality of metal particles actively bonded together.

3. A semiconductor apparatus according to claim 1, further comprising a solder layer covering the metal particle layer.

4. A semiconductor apparatus according to claim 2, wherein the metal particle is a powder of a metallic material selected from the group consisting of Ag, Pd, Cu, Au, Ag—Cu, Ag—Pd, Au—Si, and Au—Ge.

5. A semiconductor apparatus according to claim 3, wherein the solder layer comprises a solder material without containing lead, the solder material being selected from the group consisting of Sn, Sn—Ag, Sn—Ag—Cu, Sn—Sb, Bi, Bi—Ag, Bi—Cu, and Bi—Ag—Sb.

6. A method of manufacturing a semiconductor apparatus comprising the steps of:
coating metal particles protected with organic coating films thereon to at least one of a bonding surface of a front surface electrode and a boding surface of a post electrode; and
pressing and heating the metal particles between the front surface electrode and the post electrode for breaking the organic coating films to expose the metal particles and bonding the exposed metal particles actively with each other so that the front surface electrode and the post electrode are bonded to each other.

7. The method according to claim 5, further comprising the step of:
arranging a bonding agent, which liquefies by re-heating at a re-heating temperature higher than a temperature of said heating, around the first bonding layer,
liquefying the bonding agent around the first bonding layer, and
forming a second bonding layer bonded to the front surface electrode, the post electrode, and the first bonding layer.

8. The method according to claim 7, wherein the bonding agent comprises a solder that does not contain lead, and
the solder is liquefied at the re-heating temperature higher than a solid-phase-curve temperature of the solder.

9. The method according to claim 7, wherein the bonding agent, which liquefies by the re-heating, is arranged in advance on an exposed portion of the post electrode other than a portion bonded by the first bonding layer or on an exposed portion of the front surface electrode other than a portion bonded by the first bonding layer, and the bonding agent is melted by the re-heating.
